(19) United States
(12) Patent Application Publication
(10) Pub. No.: US 2012/0248616 A1
(43) Pub. Date: Oct. 4, 2012

(54) ELECTRONIC COMPONENT, ELECTRONIC EQUIPMENT, AND SOLDERING PASTE

(75) Inventors: Masayuki KITAJIMA, Kawasaki (JP); Takatoyo Yamakami, Kawasaki (JP); Takashi Kubota, Kawasaki (JP); Kuniko Ishikawa, Kawasaki (JP)

(73) Assignee: FUJITSU LIMITED, Kawasaki-shi (JP)

(21) Appl. No.: 13/361,344

(22) Filed: Jan. 30, 2012

(30) Foreign Application Priority Data
Mar. 31, 2011 (JP) 2011-080836

(51) Int. Cl. H01L 23/48; B23K 35/24

(52) U.S. Cl. 257/772; 148/24; 257/E23.01

(57) ABSTRACT

To provide an electronic component, containing: a wiring board containing electrode pads; a component including a plurality of electrodes, the component being mounted on the wiring board; a sealing resin covering the component; and a plurality of terminals configured to connect a wiring provided within the wiring board to an external substrate, wherein the plurality of electrodes and the electrode pads are connected with solder, and wherein a first resin layer and a second resin layer are provided between the solder and the sealing resin in this order from the side of the solder, where the first resin layer has a first Young's modulus and the second resin layer has a second Young's modulus larger than the first Young's modulus.

### CROSS-REFERENCE TO RELATED APPLICATIONS

This application is based upon and claims the benefit of priority of the prior Japanese Patent Application No. 2011-080836, filed on Mar. 31, 2011, the entire contents of which are incorporated herein by reference.

### FIELD

The embodiments discussed herein relate to an electronic component, electronic equipment, and a soldering paste.

### BACKGROUND

Conventionally, when an electronic component, in which a chip component, a semiconductor component, or the like is sealed with a sealing resin, is subjected to second reflow for mounting the electronic component on an external printed circuit board, it is important to prevent solder from remelting.

In the case where the solder is remelted at the second reflow, the soldered part of the chip component or the like in the electronic component is remelted, and the sealing resin is peeled. Then, the melted solder moves into a minute space formed by the pealing of the sealing resin, which causes a short circuit between electrodes.

To solve the problem as mentioned, for example, there are disclosed a soldering paste containing balls formed of Cu alone, and a Sn-based solder, and electronic equipment using the soldering paste (see, for example, Japanese Patent (JP-B) Nos. 3558063 and 3414388). In the disclosed technique, Cu is not smoothly diffused because of the oxidized film remained on surfaces of Cu balls, contact failures between the solder and the Cu balls, and insufficient heating temperature and heating duration, and therefore the melted solder is remained, which maintains the melting point of the soldering paste without changing. Therefore, remelting of the solder occurs at the second reflow. As a result of the remelting, there is a problem that a short circuit occurred between the electrodes by the melted solder.

Accordingly, it is desired to provide a soldering paste capable of preventing the aforementioned short circuit between electrodes, an electronic component using the soldering paste, and electronic equipment using the electronic component.

### SUMMARY

The disclosed electronic component contains: a wiring board containing electrode pads; a component including a plurality of electrodes, the component being mounted on the wiring board; a sealing resin covering the component; and a plurality of terminals configured to connect a wiring provided within the wiring board to an external substrate, wherein the plurality of electrodes and the electrode pads are connected with solder, and wherein a first resin layer and a second resin layer are provided between the solder and the sealing resin in this order from the side of the solder, where the first resin layer has a first Young's modulus and the second resin layer has a second Young's modulus larger than the first Young's modulus.

The disclosed electronic equipment contains the disclosed electronic component.

The disclosed soldering paste contains solder, and a resin composition containing a material for forming a first resin layer having a first Young's modulus, and a second resin layer having a second Young's modulus larger than the first Young's modulus.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a schematic cross-sectional view illustrating a solder joint part using the disclosed soldering paste.

FIG. 2A is a schematic cross-sectional view for explaining one example of a production process of the disclosed electronic component.

FIG. 2B is a schematic cross-sectional view for explaining the example of a production process of the disclosed electronic component.

FIG. 2C is a schematic cross-sectional view for explaining the example of a production process of the disclosed electronic component.

FIG. 3A is a schematic cross-sectional view for explaining another example of a production process of the disclosed electronic component.

FIG. 3B is a schematic cross-sectional view for explaining the aforementioned another example of a production process of the disclosed electronic component.

FIG. 3C is a schematic cross-sectional view for explaining the aforementioned another example of a production process of the disclosed electronic component.

FIG. 4 is a flow chart illustrating one example of a production process of the disclosed electronic component and electronic equipment.

FIG. 5A is a schematic top view for explaining one example of a production process of the disclosed electronic component and electronic equipment.

FIG. 5B is a schematic top view for explaining the example of a production process of the disclosed electronic component and electronic equipment.

FIG. 5C is a schematic top view for explaining the example of a production process of the disclosed electronic component and electronic equipment.

FIG. 5D is a schematic top view for explaining the example of a production process of the disclosed electronic component and electronic equipment.

FIG. 5E is a schematic top view for explaining the example of a production process of the disclosed electronic component and electronic equipment.

FIG. 5F is a schematic top view for explaining the example of a production process of the disclosed electronic component and electronic equipment.

FIG. 5G is a schematic top view for explaining the example of a production process of the disclosed electronic component and electronic equipment.

FIG. 6A is a schematic cross-sectional view for explaining one example of a production process of the disclosed electronic component and electronic equipment.

FIG. 6B is a schematic cross-sectional view for explaining the example of a production process of the disclosed electronic component and electronic equipment.

FIG. 6C is a schematic cross-sectional view for explaining the example of a production process of the disclosed electronic component and electronic equipment.

FIG. 6D is a schematic cross-sectional view for explaining the example of a production process of the disclosed electronic component and electronic equipment.

FIG. 6E is a schematic cross-sectional view for explaining the example of a production process of the disclosed electronic component and electronic equipment.

FIG. 6F is a schematic cross-sectional view for explaining the example of a production process of the disclosed electronic component and electronic equipment.

FIG. 6G is a schematic cross-sectional view for explaining the example of a production process of the disclosed electronic component and electronic equipment.

FIG. 7A is a schematic cross-sectional view illustrating a state where a space is formed within an electronic component during a second reflow operation.

FIG. 7B is a schematic cross-sectional view illustrating a state where the melted solder enters the space formed within the electronic component, causing a short circuit between the electrodes.

### DESCRIPTION OF EMBODIMENTS

### (Soldering Paste)

The soldering paste contains at least solder and a resin composition, and may further contain other materials.

### <Solder>

The solder is appropriately selected depending on the intended purpose without any restriction, but the solder preferably contains Sn together with Bi and/or Ag.

Examples of the solder include Sn—Cu solder, Sn—Ag—Cu solder, and Sn—Ag—Cu—Bi solder.

Examples of the solder containing Sn and Ag include (Sn-3Ag-0.5Cu) solder containing Sn as a main component, Ag in an amount of about 3% by mass, and Cu in an amount of about 0.5% by mass.

The solder is preferably a lead-free solder in view of environmental friendliness.

An amount of the solder is appropriately selected depending on the intended purpose without any restriction, but the amount thereof is preferably 80 parts by mass to 95 parts by mass relative to 100 parts by mass of the soldering paste. When the amount of the solder is smaller than 80 parts by mass, the amount of the solder is insufficient, which may cause connecting failures of the solder, such as freaking. When the amount thereof is larger than 95 parts by mass, a coating ability of the resulting soldering paste may not be desirable. Use of the solder in the amount of the aforementioned preferable range is advantageous as the resulting solder paste does not cause connecting failures, or does not have undesirable coating ability.

The solder preferably contain Cu powder. By adding the Cu powder into the solder, the Cu powder forms an intermetallic compound with Sn, which increases the melting point of the solder, to thereby suppress remelting of the solder during the second reflow process.

An amount of the Cu powder is appropriately selected depending on the intended purpose without any restriction.

### <Resin Composition>

The resin composition contains at least a material for forming a first resin layer having a first Young's modulus, and a material for forming a second resin layer having a second Young's modulus, and may further contain other materials.

—Material for Forming First Resin Layer having First Young's Modulus—

The material for forming a first resin layer having a first Young's modulus is appropriately selected depending on the intended purpose without any restriction, but the material for forming the first resin layer preferably contains at least one selected from the group consisting of a silicone resin, a polyurethane resin, a low density polyethylene resin, a fluororesin, and a rubber-based resin.

The first Young's modulus of the first resin layer is appropriately selected depending on the intended purpose without any restriction, but the first Young's modulus is preferably 0.001 GPa to 0.5 GPa.

The material for forming the first resin layer may be a solid resin or a liquid resin at room temperature.

An amount of the material for forming the first resin layer contained in the soldering paste is appropriately selected depending on the intended purpose without any restriction, but the amount thereof is preferably 1 part by mass to 19 parts by mass relative to 100 parts by mass of the soldering paste. When the amount of the material for forming the first resin layer is smaller than 1 part by mass, a resulting resin layer is thinly formed, which may not be able to sufficiently prevent a short circuit occurred between electrodes. When the amount of the material for forming the first resin layer is larger than 19 parts by mass, a proportion of the solder in the soldering paste reduces, which may cause solder connection failures, such as peeling of a sealing resin.

—Material for forming Second Resin Layer having Second Young's Modulus—

A material for forming the second resin layer having the second Young's modulus is appropriately selected depending on the intended purpose without any restriction, provided that the material has larger Young's modulus than the first Young's modulus. The material for forming the second resin layer is preferably at least one selected from the group consisting of an epoxy resin, an acrylic resin, a high density polyethylene resin, a nylon resin, polystyrene, and a polyester resin.

The second Young's modulus of the second resin layer is appropriately selected depending on the intended purpose without any restriction, provided that it is a value larger than the first Young's modulus, but it is preferably 1.0 GPa to 30 GPa.

An amount of the material for forming the second resin layer in the soldering paste is appropriately selected depending on the intended purpose without any restriction, but the amount thereof is preferably 1 part by mass to 19 parts by mass, relative to 100 parts by mass of the soldering paste. When the amount of the material for forming the second resin layer is smaller than 1 part by mass, the resulting second resin layer is formed thin, which may not be able to sufficiently prevent a short circuit occurred between electrodes. When the amount thereof is larger than 19 parts by mass, the amount of the solder in the soldering paste became small, which may cause connection failures of the solder, such as peeling of a sealing resin.

A combination of the material for forming the first resin layer and the material for forming the second layer is appropriately selected depending on the intended purpose without any restriction, but the combination thereof is preferably a combination of a silicone resin and an epoxy resin, a combination of a fluororesin and an epoxy resin, a combination of a low density polyethylene resin and an epoxy resin, or a combination of a fluororesin and a nylon resin.

The Young's modulus is measured, for example, by the following method.

The Young's modulus is measured in accordance with JIS K 7161-1994 (Japanese translation of ISO 527-1). As for a measuring device, a universal precision testing machine 2020 manufactured by INTESCO Co., Ltd. is used. As for a test piece, a dumbbell test piece No. 3 (JIS K 7161) is used. The measurement is performed at tensile speed of 20 mm/min.

In the case where the material for forming the resin layer is a thermoset resin, the dumbbell test piece No. 3 (JIS K 7161) is prepared by after applying a releasing agent to a mold JIS K 7161, pouring a thermoset resin into the mold, and heating at 160° C. for 60 seconds.

In the case where the material for forming the resin layer is a resin cured by UV rays (i.e. LTV curable resin), the dumbbell test piece No. 3 (JIS K 7161) is prepared by after applying a releasing agent to a mold JIS K 7161 (made of glass), pouring a LTV curable resin into the mold, and applying UV rays at 200 mW/cm² for 60 seconds. For the UV radiation, a 1,000 W high pressure mercury lamp (wide band of wavelength) is used as a light source for UV curing.

Moreover, the first resin layer and the second resin layer are preferably formed of a resin composition cured by LTV rays. In this case, the resin composition is a resin composition which is cured by LTV rays, and contains a UV shielding material and a UV curable resin.

The UV shielding material is appropriately selected depending on the intended purpose without any restriction, provided that it is a material capable of shielding LTV rays. Examples of the LTV shielding material include carbon powder.

The UV curable resin is appropriately selected depending on the intended purpose without any restriction. Examples of the UV curable resin include a UV curable epoxy resin, a UV curable acrylic resin, a LTV curable polyester resin, a UV curable polyurethane resin, and a UV curable silicone resin. Among them, the UV curable epoxy resin is preferable. These may be used independently, or in combination.

### <Other Materials>

The aforementioned other materials are appropriately selected depending on the intended purpose without any restriction, and examples thereof include rosin, an activator, a dispersing agent, and a metal adsorbing material.

The activator is appropriately selected depending on the intended purpose without any restriction, provided that it is a material capable of reducing oxides, sulfides, hydroxides, chlorides, sulfates, and carbonates present on the metal surface to clean the metal. Examples of the activator include diethyl amine chloride, and diethyl amine oxalate.

The dispersing agent is appropriately selected depending on the intended purpose without any restriction, provided that it is a dispersing agent capable of dispersing powder components, such as the UV shielding material.

The metal adsorbing material is appropriately selected depending on the intended purpose without any restriction, and examples thereof include imidazole, benzimidazole, alkylbenzimidazole, benzotriazol, and mercaptobenzothiazole. By mixing the metal adsorbing material with the material for forming the first resin layer, the first resin layer is easily formed on a surface of the solder.

The soldering paste is used, for example, by applying on an electrode pad on a wiring board by printing or the like in an electronic component in which a component such as a chip component, and a semiconductor component is encapsulated with a sealing resin. On the soldering paste applied on the electrode pad, the component such as a chip component, and semiconductor component is placed, and heat (first reflow), and optionally UV radiation are applied so that the electrode pad and an electrode of the component such as a chip component, and a semiconductor component are connected with solder, and at the same time the solder contained in the soldering paste is retained on the electrode pad of the wiring board. Moreover, a first resin layer (e.g., a resin layer having Young's modulus of 0.001 GPa to 0.5 GPa) and a second resin layer (e.g., a resin layer having Young's modulus of 1.0 GPa to 30 GPa) are formed in this order on a surface of the solder. These resin layers are formed in the aforementioned order owing to a difference in specific gravity, a difference in surface tension, and a function of the dispersing agent. Then, the component such as a chip component and a semiconductor component on the wiring board is encapsulated with a sealing resin, so that a first resin layer (e.g., a resin layer having the Young's modulus of 0.001 GPa to 0.5 GPa) and a second resin layer (e.g., a resin layer having the Young's modulus of 1.0 GPa to 30 GPa) are formed between the solder and the sealing resin in this order from the side of the solder.

The encapsulated electronic component is connected to an external substrate. For the connection, a terminal of the electronic component and a lead terminal of the substrate are heated (second reflow) to be solder jointed. During the second reflow, there are cases where the solder within the electronic component may be melted.

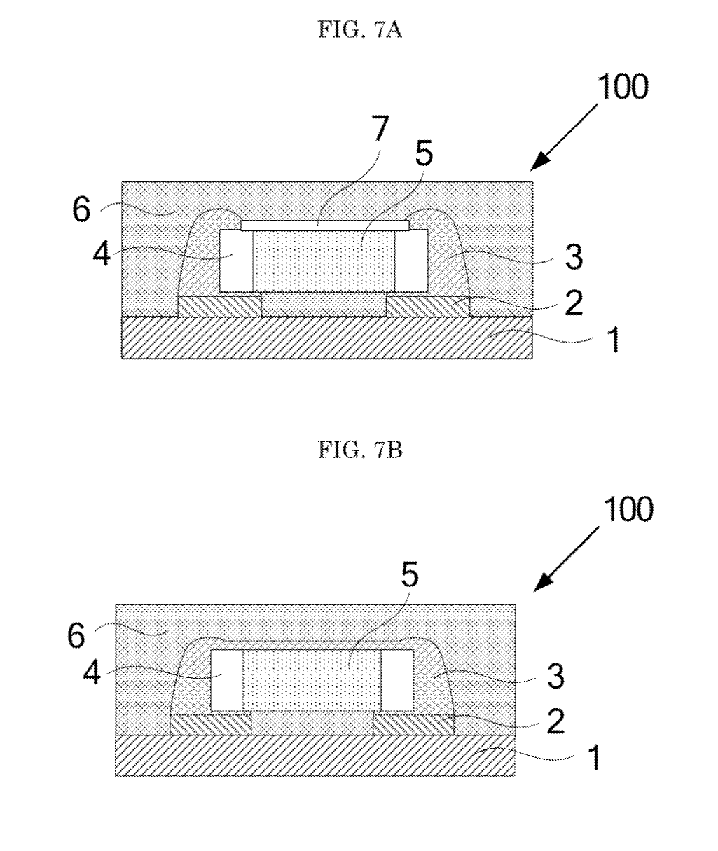

The melted solder may move into a space in the electronic component, which may cause a short circuit between the electrodes. This situation is explained with reference to FIGS. 7A to 7B. FIG. 7A is a schematic cross-sectional view illustrating a state where a space is formed within the electronic component at the time of the second reflow. FIG. 7B is a schematic cross-sectional view illustrating a state where the melted solder has moved into the space formed within the electronic component, and a short circuit is occurred between the electrodes. In the case where a conventional soldering paste is used for solder joints of the electronic component, as illustrated in FIG. 7A, within an electronic component 100 containing a wiring board 1, electrode pads 2 on the wiring board 1, solder 3, a component (e.g., a chip component) 5 connected to the wiring board 1 with the solder 3, electrodes 4 of the component 5, and a sealing resin 6 encapsulating the component 5, the sealing resin 6 is cracked, or a slight space 7 is formed between the component 5 and the sealing resin 6, both because of the deformation of the sealing resin 6 or the like, resulted from the volume change (expansion) caused by the melted solder 3 during the second reflow performed for solder jointing the electronic component 100 to an external substrate. Since the melted solder 3 moves into the slight space 7 by capillarity or the like, as illustrated in FIG. 7B, the electrodes 4 of the component 5 are electrically connected, or the electrode 4 of the component 5 and the electrode 4 of another component 5 are electrically connected, causing a short circuit (may also referred to as “flash phenomenon” hereinafter).

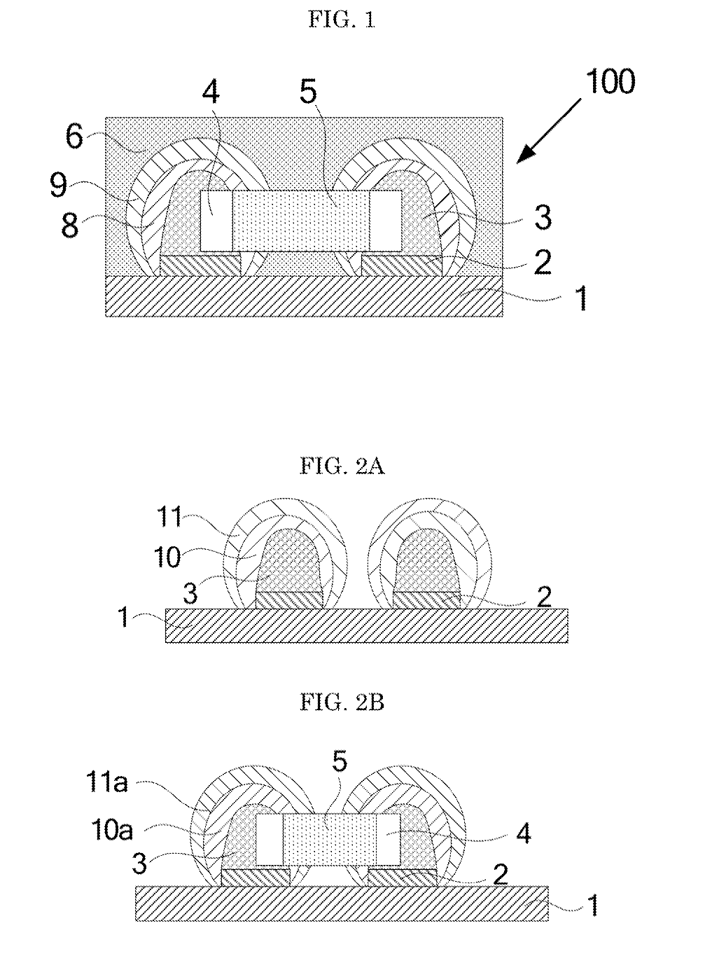

In the case where the disclosed soldering paste is used for solder joints in the electronic component 100, as illustrated in FIG. 1 (FIG. 1 is a schematic cross-sectional view illustrating a solder joint using the disclosed soldering paste), a first resin layer (e.g., a resin layer having Young's modulus of 0.001 GPa to 0.5 GPa) 8 and a second resin layer (e.g., a resin layer having Young's modulus of 1.0 GPa to 30 GPa) 9 are formed between the solder 3 and the sealing resin 6 in this order from the side of the solder 3 as described earlier. Therefore, even if the solder 3 is melted at the second reflow to change its volume (cause expansion), the first resin layer 8 absorbs the changed amount in the volume of the solder 3. Since the second resin layer 9 is present, moreover, the second resin layer 9 prevents a deformation of the first resin layer 8 when sealed with the sealing resin 6. Accordingly, a strongly adhered resin layer is formed. Because of the reasons as mentioned, use of the disclosed soldering paste can prevent cracking of the sealing resin and formation of a space between a component (e.g., a chip component) and the sealing resin due to the volume change (expansion) of the solder even when the solder is melted by the second reflow. As a result, a short circuit caused between electrodes of a component, or between an electrode of a component and an electrode of another component by the melted solder can be prevented.

(Electronic component)

The electronic component contains at least a wiring board, a component, a sealing resin, and a terminal, and may further contain other members, if necessary.

The wiring board contains electrode pads.

The component has a plurality of electrodes, which are connected to the electrode pads with solder.

Between the solder and the sealing resin, a first resin layer having a first Young's modulus and a second resin layer having a second Young's modulus larger than the first Young's modulus are formed in this order from the side of the solder.

### <Wiring Board>

The wiring board is appropriately selected depending on the intended purpose without any restriction, provided that it is an insulating substrate, and has an electrode pad. Examples thereof include a ceramic substrate, and a glass epoxy substrate.

A size of the wiring board is appropriately selected depending on the intended purpose without any restriction. For example, the size of the substrate is 10 mm to 200 mm in length, 10 mm to 200 mm in width, and 0.5 mm to 5 mm in thickness.

A shape of the plane of the wiring board at which the component is mounted is appropriately selected depending on the intended purpose without any restriction, and examples the shape include square, rectangle, and circle.

### <Component>

The component appropriately selected depending on the intended purpose without any restriction, provided that it has a plurality of electrodes. Examples of the component include chip component, and semiconductor component.

The component is mounted on the wiring board.

The chip component is appropriately selected depending on the intended purpose without any restriction, and examples thereof include a condenser, and a resistor.

The semiconductor component is appropriately selected depending on the intended purpose without any restriction, and examples thereof include an integrated circuit, a large scale integrated circuit, a transistor, a thyristor, and a diode.

These may be used independently, or in combination.

A size of the component is appropriately selected depending on the intended purpose without any restriction, and examples thereof include a 1608 type (1.6 mm×0.8 mm×0.8 mm), a 1005 type (1 mm×0.5 mm×0.5 mm), and a 0603 type (0.6 mm×0.3 mm×0.3 mm).

In the electronic component, generally, a plurality of components is mounted on the wiring board.

Note that, all of the components do not need to be solder jointed in the electronic component, as long as at least part of the components are solder jointed.

It is also acceptable that part of the components is connected with a lead frame.

### <Sealing Resin>

The sealing resin is appropriately selected depending on the intended purpose without any restriction, provided that the sealing resin is a resin covering the component.

A material of the sealing resin is appropriately selected depending on the intended purpose without any restriction, and examples thereof include thermoset resins such as a phenol resin, a melamine resin, an epoxy resin, and a polyester resin.

A method for encapsulating the component is appropriately selected depending on the intended purpose without any restriction. Examples of the method include potting where the component is set with the thermoset resin so as to cover and include the component in the thermoset resin, and transfer molding using the thermoset resin.

The encapsulation by the sealing resin in the electronic component may be carried out on the component, or on the entire surface of the wiring board.

### <Terminal>

The terminal is appropriately selected depending on the intended purpose without any restriction, provided that it is a terminal for connecting a wiring within the wiring board to an external substrate. Examples of the terminal include a lead wire.

The electronic component has a plurality of the terminals.

A shape of the terminal is appropriately selected depending on the intended purpose without any restriction, and examples thereof include a wire shape.

A material of the lead wire is appropriately selected depending on the intended purpose without any restriction, and examples thereof include gold, silver, and copper.

### <Solder>

The solder is appropriately selected depending on the intended purpose without any restriction, but the solder is preferably solder of the soldering paste. When a plurality of the electrode and the electrode pad are connected, therefore, the soldering paste is preferably used. By using the soldering paste, the first resin layer having the first Young's modulus and the second resin layer having the second Young's modulus larger than the first Young's modulus are easily formed between the solder and the sealing resin, in this order from the side of the solder.

### <Resin Layer>

—First Resin Layer having First Young's Modulus—

The first resin layer having the first Young's modulus is appropriately selected depending on the intended purpose without any restriction, but the first resin layer preferably contains at least one selected from the group consisting of a silicone resin, a polyurethane resin, a low density polyethylene resin, a fluororesin, and a rubber-based resin. These resins may be crosslinked.

The first Young's modulus of the first resin layer is appropriately selected depending on the intended purpose without any restriction, but it is preferably 0.001 GPa to 0.5 GPa.

A shape of the first resin layer is appropriately selected depending on the intended purpose without any restriction, and examples thereof include a shape which covers a surface of the solder. Namely, the first resin layer may be in any appropriate shape corresponding to the shape of the solder. Note that the first resin layer is preferably not present between the electrode pad and the solder, or between an electrode of the component and the solder, because it is preferred that the first resin layer be formed so as not to interfere a solder joint between the electrode pad of the wiring board and the electrode of the component.

A thickness of the first resin layer is appropriately selected depending on the intended purpose without any restriction. The first resin layer is formed so as to cover a surface of the solder on the wiring board, and a thickness of the first resin layer is not necessary uniform. For example, a thickness of the first resin layer is 10 μm or more but less than 50 μm in the thin part of the first resin layer, and is 50 μm to 100 μm in the thick part thereof.

A volume ratio of the first resin layer to the solder is appropriately selected depending on the intended purpose without any restriction, but it is preferably 20% by volume to 80% by volume relative to the solder in the solder joint.

—Second Resin Layer having Second Young's Modulus—

The second resin layer having the second Young's modulus is appropriately selected depending on the intended purpose without any restriction, but the second resin layer preferably contains at least one selected from the group consisting of an epoxy resin, an acrylic resin, a high density polyethylene resin, a nylon resin, polystyrene, and a polyester resin. These resins may be crosslinked.

The second Young's modulus of the second resin layer is appropriately selected depending on the intended purpose without any restriction, provided that it is larger than the first Young's modulus of the first resin layer. The second Young's modulus of the second resin layer is preferably 1.0 GPa to 30 GPa.

A shape of the second resin layer is appropriately selected depending on the intended purpose without any restriction, and examples of the shape of the second resin layer include a shape covering a surface of the first resin layer. Namely, the second resin layer may be in any appropriate shape corresponding to the shape of the first resin layer. Note that the second resin layer is preferably not present between the electrode pad and the solder, or between an electrode of the component and the solder, because it is preferred that the second resin layer be formed so as not to interfere a solder joint between the electrode pad of the wiring board and the electrode of the component.

A thickness of the second resin layer is appropriately selected depending on the intended purpose without any restriction. The second resin layer is formed so as to cover a surface of the first resin layer, and a thickness of the second resin layer is not necessary uniform. For example, a thickness of the second resin layer is 10 μm or more but less than 50 μm in the thin part of the second resin layer, and is 50 μm to 100 μm in the thick part thereof.

A volume ratio of the second resin layer to the solder is appropriately selected depending on the intended purpose without any restriction, but the volume ratio of the second resin layer is preferably 20% by volume to 80% by volume relative to the solder in the solder joint part.

Moreover, the first resin layer and the second resin layer are preferably formed of a resin composition cured by LTV rays.

A combination of the first resin layer and the second resin layer is appropriately selected depending on the intended purpose without any restriction, but the combination thereof is preferably a combination of a silicone resin and an epoxy resin, a combination of a fluororesin and an epoxy resin, a combination of a low density polyethylene resin and an epoxy resin, and a fluororesin and a nylon resin.

The first resin layer and second resin layer may be each a single layer or multiple layers.

### —Formation Method of Resin Layer—

A method for forming the first resin layer and the second resin layer between the solder and the sealing resin in this order from the side of the solder is appropriately selected depending on the intended purpose without any restriction. Examples of the method include a method utilizing a difference in specific gravity between the materials contained in the resin composition of the soldering paste, or a difference in surface tension between the materials contained in the resin composition of the soldering paste, or a dispersing agent; and a method using UV radiation. Note that, these methods may be used in combination.

### —Difference in Specific Gravity—

The method for forming the resin layer utilizing a difference in specific gravity includes, for example, a method for forming the resin layer, which uses a combination of a silicone resin and an epoxy resin, a combination of a fluororesin and an epoxy resin, or a combination of a low density polyethylene resin and an epoxy resin, as the material for forming the first resin layer and the material for forming the second resin layer in the resin composition of the soldering paste, and uses specific gravity difference between these resins.

The specific gravity of the silicone resin is generally more than 2.0 up to about 4.0, and the specific gravity of the epoxy resin is generally in an approximate range of 0.9 to 2.0. Therefore, a difference in these specific gravities is utilized to form the resin layer.

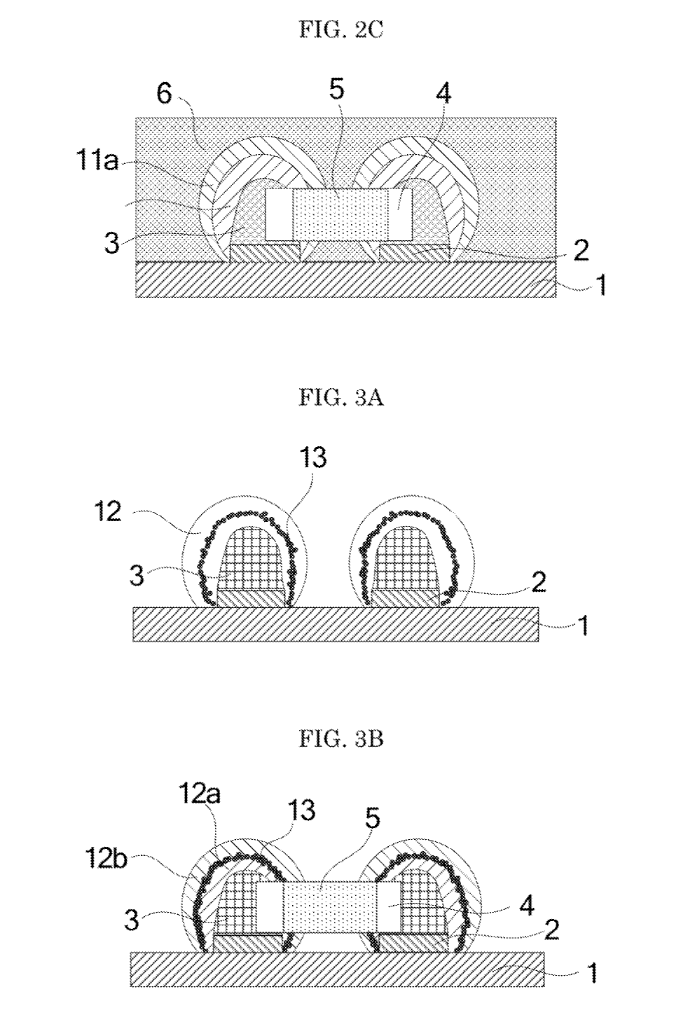

A specific example thereof is explained with reference to FIGS. 2A to 2C. FIGS. 2A to 2C are schematic cross-sectional views for explaining one example of the production process of the disclosed electronic component. A soldering paste containing solder 3, a solid thermosetting silicone resin 10 as a material for forming a first resin layer (e.g., a resin layer having Young's modulus of 0.001 GPa to 0.5 GPa), and a liquid thermosetting epoxy resin 11 as a material for forming a second resin layer (a resin layer having Young's modulus of 1.0 GPa to 30 GPa) is printed on a wiring board 1 having electrode pads 2. At the time of printing, heating (e.g., at the heating temperature of 80° C. to 160° C., for the duration of 30 seconds to 5 minutes) is performed, if necessary. Thereafter, the resultant is left to stand for a while (e.g. 15 minutes to 60 minutes) so that the thermosetting silicone resin 10 is laminated on the surface of the solder 3, and the thermosetting epoxy resin 11 is laminated on the outer surface of the thermosetting silicone resin 10, as illustrated in FIG. 2A, as a result of the difference in the specific gravity between the thermosetting silicone resin 10 and the thermosetting epoxy resin 11. Thereafter, a component (e.g., a chip component) 5 having electrodes 4 is placed on the solder 3, followed by heating (performing first reflow), to thereby connect the component 5 to the electrode pads 2 by solder joints, as illustrated in FIG. 2B. At the same time, the thermosetting silicone resin 10 is cured to become a crosslinked resin 10a of the thermosetting silicone resin, and the thermosetting epoxy resin 11 is cured to become a crosslinked resin 11a of the thermosetting epoxy resin. By sealing with a sealing resin 6, as illustrated in FIG. 2C, the crosslinked resin of the thermosetting silicone resin (a resin layer having Young's modulus of 0.001 GPa to 0.5 GPa) 10a and the crosslinked resin of the thermosetting epoxy resin (a resin layer having Young's modulus of 1.0 GPa to 30 GPa) 11a are formed between the solder 3 and the sealing resin 6 in this order from the side of the solder 3.

Note that, the thermosetting silicone resin and thermosetting epoxy resin may be completely cured by the heating (the first reflow), or may not be completely cured (half-cured) by the heating (the first reflow) and may be completely cured at the time when sealed with the sealing resin.

### ——Difference in Surface Tension——

The method for forming the resin layer using a difference in surface tension include, for example, a method for forming the resin, which uses a combination of a silicone resin and an epoxy resin, or a combination of a fluororesin and a nylon resin as the material for forming the first resin layer and the material for forming the second resin layer contained in the resin composition of the soldering paste, and uses a difference in surface tension between these resins.

The surface tension of the silicone resin is generally in an approximate range of 15 dyn/cm (20° C.) to 30 dyn/cm (20° C.), and the surface tension of the epoxy resin is generally in an approximate range of 40 dyn/cm (20° C.) to 50 dyn/cm (20° C.). Therefore, the resin layer is formed by using a difference in these surface tensions.

Specific examples thereof include a similar method to the specific example of the method utilizing a difference in specific gravity.

### ——UV Radiation——

A method for forming the resin layer by UV radiation includes, for example, a method for as the resin composition for the soldering paste, using a resin composition cured by UV ray, which contains a LTV shielding material and a resin cured by LTV rays (i.e. a UV curable resin).

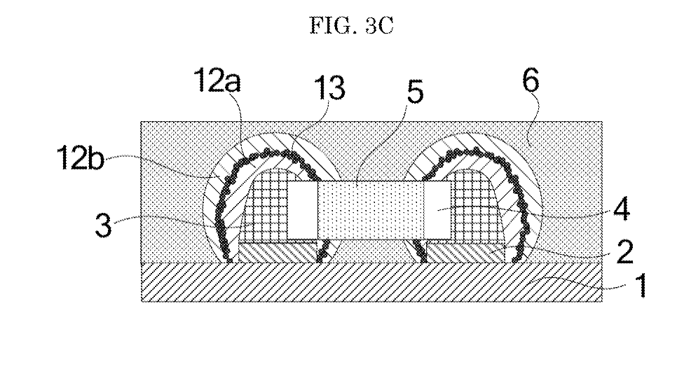

Specific example of the method is explained with reference to FIGS. 3A to 3C. FIGS. 3A to 3C are schematic cross-sectional views for explaining one example of the production process of the disclosed electronic component. A soldering paste containing solder 3, a UV curable epoxy resin 12 as a material for forming a first resin layer and second resin layer, carbon powder 13 as a UV shielding material, and a dispersing agent (not illustrated) for dispersing the UV shielding material is printed on a wiring board 1 having electrode pads 2. Thereafter, the printed soldering paste is left to stand for a while (e.g., 15 minutes to 60 minutes) so that, as illustrated in FIG. 3A, particles of the carbon powder 13 are aggregated due to the function of the dispersing agent, and are distributed only in the middle of the UV curable epoxy resin 12. Thereafter, a component (e.g. a chip component) 5 having electrodes 4 is placed on the solder 3, followed by heating (first reflow), to thereby connect the component 5 to the electrode pads 2 with solder joints. Then, UV radiation is applied, so that, as illustrated in FIG. 3B, a crosslinked resin having a low curing rate (a first resin layer, e.g., a resin layer having Young's modulus of 0.001 GPa to 0.5 GPa) 12a is formed as the UV curable epoxy resin 12 at the side of the solder 3 does not receive sufficient UV rays because of the presence of the carbon powder 13. Meanwhile, the UV curable epoxy resin 12 present at outer side (a side of a radiation source) from the carbon powder 13 is sufficiently cured by UV rays to form a crosslinked resin having a high curing rate (a second resin layer, e.g., a resin layer having Young's modulus of 1.0 GPa to 30 GPa) 12b. By sealing the resultant with a sealing resin 6, as illustrated in FIG. 3C, the crosslinked resin having the low curing rate (the first resin layer, e.g., the resin layer having Young's modulus of 0.001 GPa to 0.5 GPa) 12a, and the crosslinked resin having the high curing rate (the second resin layer, e.g., the resin layer having Young's modulus of 1.0 GPa to 30 GPa) 12b are formed between the solder 3 and the sealing resin 6 in this order from the side of the solder 3.

The irradiance of the UV radiation is appropriately selected depending on the intended purpose without any restriction, but it is preferably 200 mW/cm² to 500 mW/cm² for 30 seconds to 2 minutes.

### (Electronic Equipment)

The electronic equipment contains at least the electronic component, and may further contain other components.

The electronic component is mounted on the electronic equipment by connecting terminals of the electronic component to the electronic equipment with solder.

Examples of the electronic equipment include an arithmetic processing unit such as a personal computer, and a server; a communication equipment such as a mobile phone, and a radio; an office appliance such as a printer, and a photocopier; and an AV equipment such as a television, and an integrated music system; and a domestic appliance such as an air conditioner, and a refrigerator.

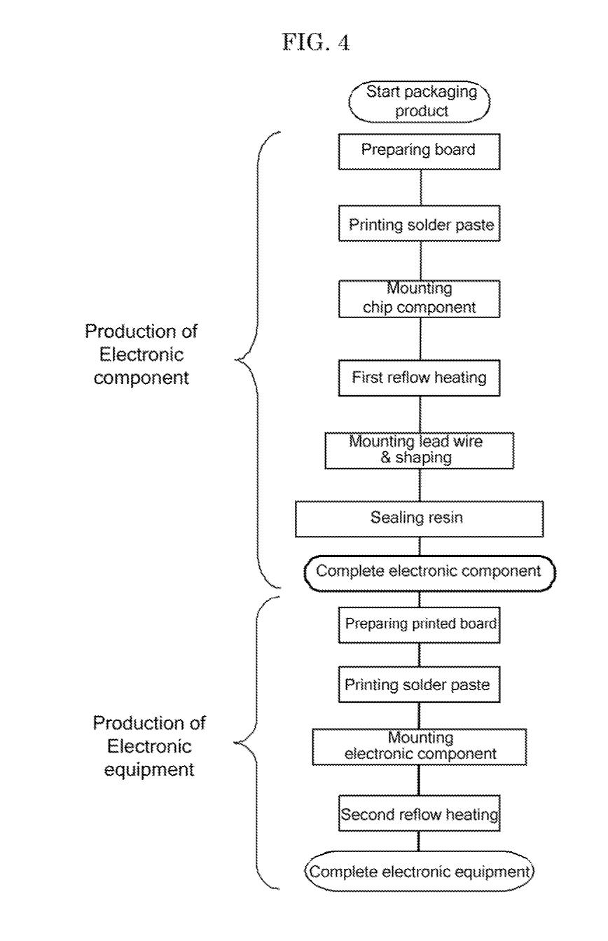

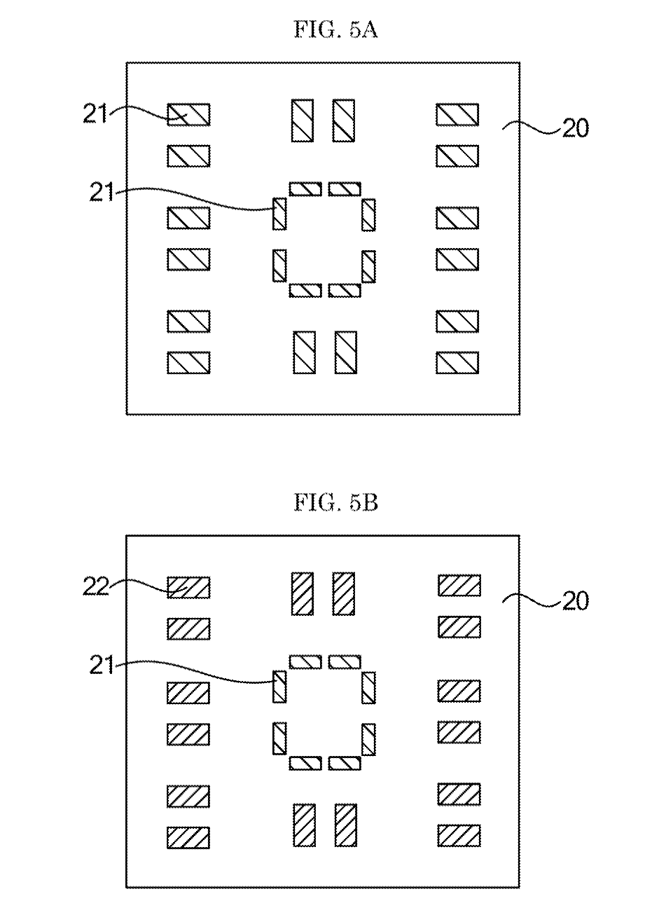

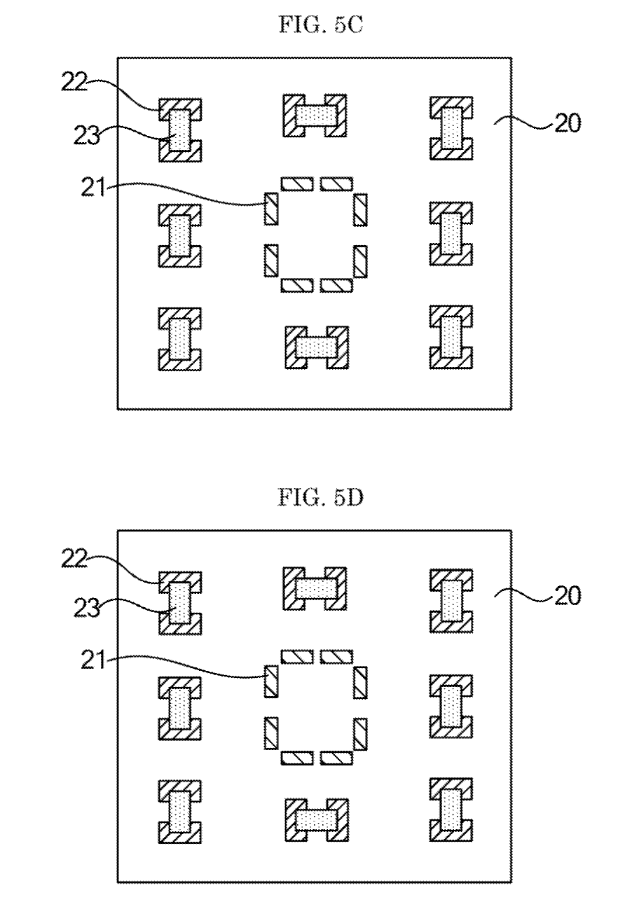

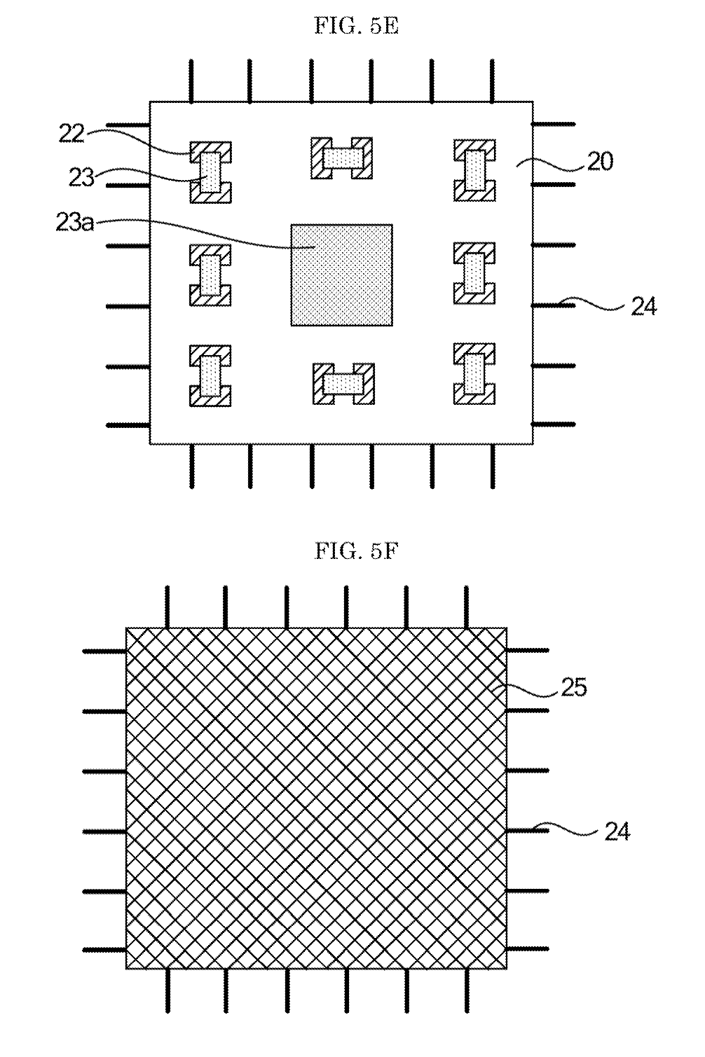

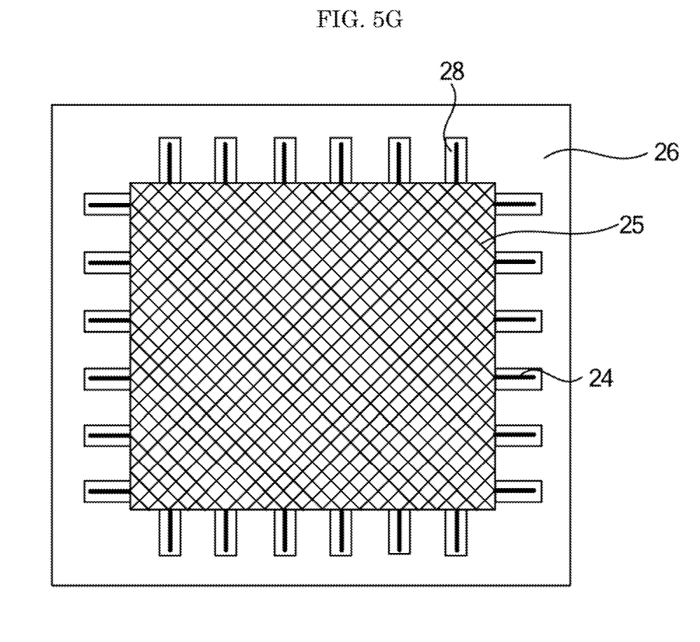

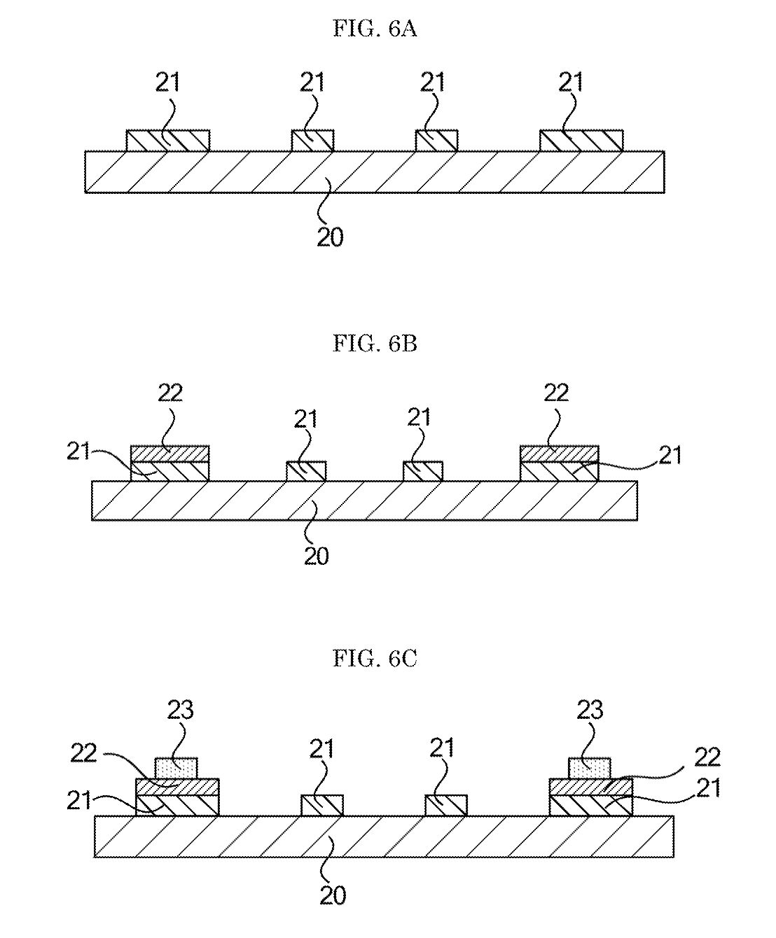

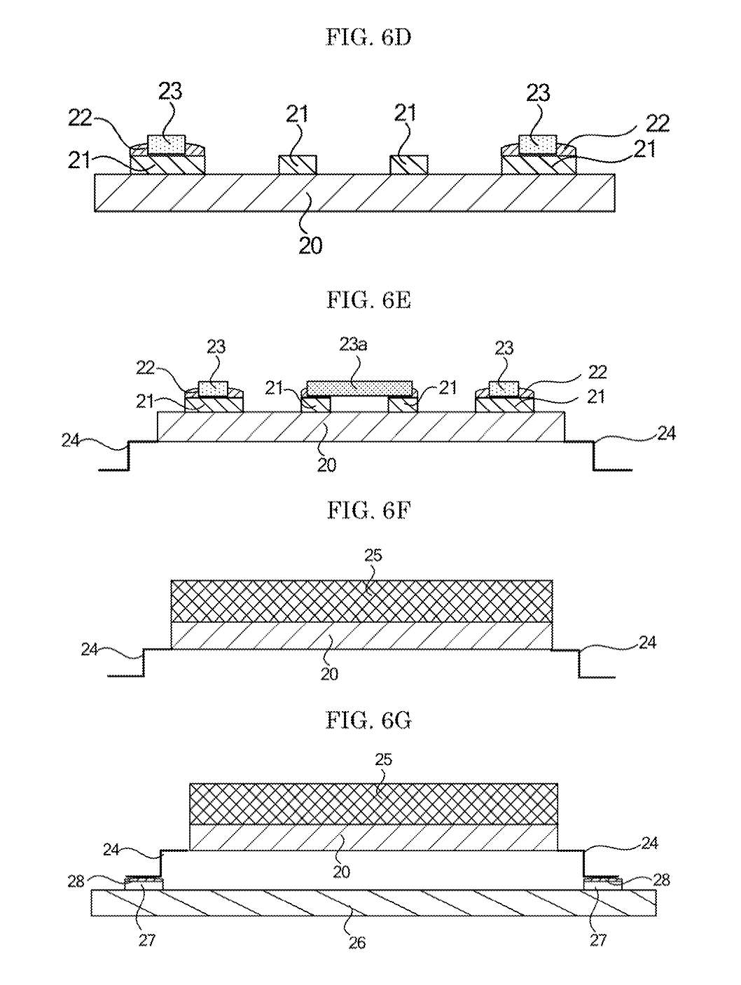

One example of the production method of the electronic component and electronic equipment is illustrated in a flow chart of FIG. 4, in FIGS. 5A to 5G, and in FIGS. 6A to 6G. FIG. 4 is a flow chart illustrating one example of a production process of the disclosed electronic component, and electronic equipment. FIGS. 5A to 5G are schematic top views for explaining one example of a production process of the disclosed electronic component, and electronic equipment. FIGS. 6A to 6G are schematic cross-sectional views for explaining one example of a production process of the disclosed electronic component, and electronic equipment.

At first, a wiring board 20 having electrode pads 21 is prepared (FIG. 5A and FIG. 6A). Subsequently, a soldering paste is printed on the wiring board 20 to place the solder 22 on the electrode pads 21 (FIG. 5B and FIG. 6B). The printing method is appropriately selected depending on the intended purpose without any restriction, and examples thereof include screen printing. Then, a plurality of components 23 are placed on the electrode pads 21 (FIG. 5C and FIG. 6C). After the components 23 are placed, first reflow heating is performed to connect the components 23 to the electrode pads 21 with solder joints (FIG. 5D and FIG. 6D). Optionally, other components 23a are further mounted, followed by mounting lead wires 24 (FIG. 5E and FIG. 6E). If necessary, shaping is then performed. Subsequently, the resultant is sealed with a sealing resin 25 to thereby produce an electronic component (FIG. 5F and FIG. 6F).

Next, a printed circuit board 26 having lead terminals 27 is prepared, and a soldering paste is applied on the printed circuit board 26 by screen printing so that the solder 28 is placed on the lead terminals 27. Subsequently, the lead wires 24 of the electronic component are arranged on the lead terminals 27 of the printed circuit board 26. Then, second reflow heating is performed to connect the electronic component to the printed circuit board 26 with solder joints (FIG. 5G and FIG. 6G). After performing other steps as necessary, electronic equipment is produced.

The disclosed electronic component can prevent a short circuit occurred between electrodes by the melted solder when the electronic component is connected to an external printed circuit board or the like with solder joints.

The disclosed electronic equipment can achieve to realize electronic equipment containing an electronic component that prevent a short circuit occurred between electrodes by the melted solder.

The disclosed soldering paste can prevent a short circuit occurred between electrodes by the melted solder when the electronic component is connected to an external printed circuit board or the like with solder joints.

The invention is specifically explained through examples thereof hereinafter, but these examples shall not be construed as to limit the scope of the invention in any way. Note that, “part(s)” in the following examples represents “part(s) by mass.”

### (Measurement of Young's Modulus)

The Young's modulus in the following Examples was measured by the following manner.

The Young's modulus was measured in accordance with JIS K 7161-1994 (Japanese translation of ISO 527-1). As for a measuring device, a universal precision testing machine 2020 manufactured by INTESCO Co., Ltd. was used. As for a test piece, a dumbbell test piece No. 3 (JIS K 7161) was used. The measurement was performed at tensile speed of 20 mm/min.

The dumbbell test piece No. 3 (JIS K 7161) of a thermoset resin was prepared by after applying a releasing agent to a mold JIS K 7161, pouring a thermoset resin into the mold, and heating at 160° C. for 60 seconds.

The dumbbell test piece No. 3 (JIS K 7161) of a UV curable resin was prepared by after applying a releasing agent to a mold JIS K 7161 (made of glass), pouring a UV curable resin into the mold, and applying UV rays at 200 mW/cm² for 60 seconds. For the UV radiation, a 1,000 W high pressure mercury lamp (wide band of wavelengths) was used as a light source for UV curing.

### Example 1

### Preparation of Soldering Paste 1

The materials of the following formulation were mixed to prepare Soldering Paste 1.

-Resin Composition-

| | |
|---|---|
| Thermosetting silicone resin (Shin-Etsu Silicone KE1830, | 6.7 parts |
| manufactured by Shin-Etsu Chemical Co., Ltd.) | |
| (Young's modulus: 0.02 GPa, solid resin, specific | |
| gravity: 2.2) | |
| Thermosetting epoxy resin (ACMEX ER-6761FA/B, | 7.7 parts |
| manufactured by Nihon Gosei Koko Co., Ltd.) | |
| (Young's modulus: 10 GPa, liquid resin, specific | |
| gravity: 1.8) | |
| Activator (diphenylguanidine hydrobromide, | 0.6 parts |
| manufactured by Kanto Chemical Co., Ltd.) | |

-Solder-

| | |
|---|---|
| Solder (M705 (SnAgCu), manufactured by Senju Metal | 85 parts |
| Industry Co., Ltd.) | |

Note that, the thermosetting silicone resin was pretreated by heating the thermosetting silicone resin at about 100° C. to cure and solidify the resin, and pulverizing to thereby turn the solid resin into a powder having the average particle diameter of 100 μm.

### <Preparation of Electronic Part, and Evaluation of Solder Short (Flash Phenomenon)>

### Preparation of Electronic Component

On a wiring board (size: 110 mm×110 mm×1.0 mm (thickness)), a copper pattern (pad size: 0.3 mm×0.3 mm, distance between pads: 0.2 mm (pitch)) was formed. On the wiring board, Soldering Paste 1 prepared above was printed using a metal screen plate and a metal squeegee. Note that, as the metal screen plate, a screen plate having a pad opening of 100%, and plate thickness of 150 μm was used. On the printed soldering paste, a chip component (0603 chip component, Sn electrode) was placed, and mounted on the board in an non oxidativity atmosphere (oxygen concentration of lower than 100 ppm), at a reflow peak temperature of 235° C.

Subsequently, after washing the wiring board, a sealing resin (an epoxy adhesive) was applied on the wiring board, and heated at 150° C. for 1 hour to cure the sealing resin, followed by leaving to stand in a high temperature high humidity environment (85° C./85% RH), to thereby prepare an electronic component. Note that, connections of lead wires were emitted.

Within the prepared electronic component, a crosslinked resin of the thermosetting silicone resin (first resin layer, a resin layer having Young's modulus of 0.02 GPa) and a crosslinked resin of the thermosetting epoxy resin solder (second resin layer, a resin layer having Young's modulus of 10 GPa) were formed in this order between the solder and the sealing resin from the side of the solder.

### Evaluation of Solder Short (Flash Phenomenon)

As a second reflow, the prepared electronic component was heated at a reflow peak temperature of 260° C. for 5 minutes.

After the second reflow, the electronic component was visually observed, a number of short circuits of the solder between the chip components, and within the component were counted, and the number of the chip components in which the solder shorts occurred was evaluated. Note that, the numbers of the chip components observed were 400.

As a result, there was no chip component causing solder shorts (flash phenomenon).

### Example 2

### Preparation of Soldering Paste 2>

The materials of the following formulation were mixed to prepare Soldering Paste 2.

-Resin Composition-

| | |
|---|---|
| Thermosetting silicone resin (Shin-Etsu Silicone KE1862, | 3.6 parts |
| manufactured by Shin-Etsu Chemical Co., Ltd.) | |
| (Young's modulus: 0.005 GPa, liquid resin, specific | |
| gravity: 3.0) | |
| Thermosetting silicone resin (Shin-Etsu Silicone KE1830, | 3.6 parts |
| manufactured by Shin-Etsu Chemical Co., Ltd.) | |
| (Young's modulus: 0.02 GPa, liquid resin, specific | |
| gravity: 2.2) | |
| Thermosetting epoxy resin (ACMEX ER-6761FA/B, | 7.7 parts |
| manufactured by Nihon Gosei Koko Co., Ltd.) | |
| (Young's modulus: 10 GPa, liquid resin, specific | |
| gravity: 1.8) | |
| Activator (diphenylguanidine hydrobromide, | 0.6 parts |
| manufactured by Kanto Chemical Co., Ltd.) | |

-Solder-

| | |
|---|---|
| Solder (M705 (SnAgCu), manufactured by Senju Metal | 85 parts |
| Industry Co., Ltd.) | |

### <Preparation of Electronic Part, and Evaluation of Solder Short (Flash Phenomenon)>

### Preparation of Electronic Component

An electronic part was prepared in the same manner as in Example 1, provided that Soldering Paste 1 was replaced with Soldering Paste 2.

Within the prepared electronic component, a crosslinked resin of the thermosetting silicone resin (Shin-Etsu Silicone KE1862) (first resin layer, a resin layer having Young's modulus of 0.005 GPa), a crosslinked resin of the thermosetting silicone resin (Shin-Etsu Silicone KE1830) (first resin layer, a resin layer having Young's modulus of 0.02 GPa), and a crosslinked resin of the thermosetting epoxy resin (second resin layer, a resin layer having Young's modulus of 10 GPa) were formed in this order between the solder and the sealing resin from the side of the solder.

### Evaluation of Solder Short (Flash Phenomenon)

The evaluation of solder shorts was performed in the same manner as in Example 1.

As a result, there was not chip component causing solder shorts (flash phenomenon).

### Example 3

### Preparation of Soldering Paste 3

The materials of the following formulation were mixed to prepare Soldering Paste 3.

-Resin Composition-

| | |
|---|---|
| UV curable epoxy resin (3113B, containing an initiator, | 12.9 parts |
| manufactured by ThreeBond Co., Ltd.) | |
| (solid resin, specific gravity: 1.13) | |
| Carbon powder (UV shielding material, manufactured by | 1.0 parts |
| Sunrex-Kogyo Co., Ltd.) | |
| Powdery dispersing agent (carboxylic acid | 0.4 parts |
| (HOOC—R—COOH) etc., manufactured by Nikko | |
| Chemicals Co., Ltd.) | |
| Activator (diethyl amine hydrochloride (HCl), | 0.7 parts |
| manufactured by Kanto Chemical Co., Ltd.) | |

-Solder-

| | |
|---|---|
| Solder (M705 (SnAgCu), manufactured by Senju Metal | 85 parts |
| Industry Co., Ltd.) | |

### <Preparation of Electronic Part, and Evaluation of Solder Short (Flash Phenomenon)>

### Preparation of Electronic Component

An electronic component was prepared in the same manner as in Example 1, provided that Soldering Paste 1 was replaced with Soldering Paste 3, and UV radiation was applied after the first reflow.

Within the prepared electronic component, an incompletely cured film of the UV curable epoxy resin (first resin layer, a resin layer having Young's modulus of 0.5 GPa) and an completely cured film of the UV curable epoxy resin (second resin layer, a resin layer having Young's modulus of 10 GPa) were formed in this order between the solder and the sealing resin from the side of the solder. Moreover, between the incompletely cured film and the completely cured film, the carbon powder serving as the UV shielding material was aggregated and a layer was formed by the aggregated carbon powder.

### Evaluation of Solder Short (Flash Phenomenon)

The evaluation of solder shorts was performed in the same manner as in Example 1.

As a result, there was not chip component causing solder shorts (flash phenomenon).

### Example 4

### Preparation of Soldering Paste 4

The materials of the following formulation were mixed to prepare Soldering Paste 4.

-Resin Composition-

| | |
|---|---|
| Thermosetting silicone resin (Shin-Etsu Silicone KE1830, | 6.24 parts |
| manufactured by Shin-Etsu Chemical Co., Ltd.) | |
| (Young's modulus: 0.02 GPa, liquid resin, specific | |
| gravity: 2.2) | |
| Thermosetting epoxy resin (ACMEX ER-6761FA/B, | 5.98 parts |
| manufactured by Nihon Gosei Koko Co., Ltd.) | |
| (Young's modulus: 10 GPa, liquid resin, specific | |
| gravity: 1.8) | |
| Metal adsorbing material (benzimidazole, manufactured | 0.26 parts |
| by Kanto Chemical Co., Ltd., solid powder) | |
| Activator (diethylamine hydrochloride(HCl), | 0.52 parts |
| manufactured by Kanto Chemical Co., Ltd.) | |

-Solder-

| | |
|---|---|
| Solder (L23 (Sn—58Bi—1.0Ag), manufactured by | 87 parts |
| Senju Metal Industry Co., Ltd.) | |

Note that, during the production of the soldering paste, the metal absorbing material was mixed with the thermosetting silicone resin first, and then other materials were mixed.

### <Preparation of Electronic Part, and Evaluation of Solder Short (Flash Phenomenon)>

### Preparation of Electronic Component

An electronic component was prepared in the same manner as in Example 1, provided that Soldering Paste 1 was replaced with Soldering Paste 4, and the temperature of the first reflow was changed to 160° C.

Within the prepared electronic component, a crosslinked resin of the thermosetting silicone resin (first resin layer, a resin layer having Young's modulus of 0.02 GPa) and a crosslinked resin of the thermosetting epoxy resin solder (second resin layer, a resin layer having Young's modulus of 10 GPa) were formed in this order between the solder and the sealing resin from the side of the solder.

### Evaluation of Solder Short (Flash Phenomenon)

The evaluation of solder shorts was performed in the same manner as in Example 1.

As a result, there was not chip component causing solder shorts (flash phenomenon).

### Comparative Example 1

### Preparation of Soldering Paste 5

The materials of the following formulation were mixed to prepare Soldering Paste 5.

-Resin Composition-

| | |
|---|---|
| Thermosetting epoxy resin (ACMEX ER-6761FA/B, | 14.4 parts |
| manufactured by Nihon Gosei Koko Co., Ltd.) | |
| (Young's modulus: 10 GPa, liquid resin, specific | |
| gravity: 1.8) | |
| Activator (diphenylguanidine hydrobromide, | 0.6 parts |
| manufactured by Kanto Chemical Co., Ltd.) | |

-Solder-

| | |
|---|---|
| Solder (M705 (SnAgCu), manufactured by Senju Metal | 85 parts |
| Industry Co., Ltd.) | |

### <Preparation of Electronic Part, and Evaluation of Solder Short (Flash Phenomenon)>

### Preparation of Electronic Component

An electronic component was prepared in the same manner as in Example 1, provided that Soldering Paste 1 was replaced with Soldering Paste 5.

Within the prepared electronic component, a crosslinked resin of the thermosetting epoxy resin (a resin layer having Young's modulus of 10 GPa) was formed between the solder and the sealing resin.

### Evaluation of Solder Short (Flash Phenomenon)

The evaluation of solder shorts was performed in the same manner as in Example 1.

As a result, a proportion of the chip components causing solder shorts (flash phenomenon) was 24%.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the sprit and scope of the invention.

What is claimed is:

1. An electronic component, comprising:
a wiring board containing electrode pads;
a component including a plurality of electrodes, the component being mounted on the wiring board;
a sealing resin covering the component; and
a plurality of terminals configured to connect a wiring provided within the wiring board to an external substrate,
wherein the plurality of electrodes and the electrode pads are connected with solder, and
wherein a first resin layer and a second resin layer are provided between the solder and the sealing resin in this order from the side of the solder, where the first resin layer has a first Young's modulus and the second resin layer has a second Young's modulus larger than the first Young's modulus.

2. The electronic component according to claim 1, wherein the first Young's modulus of the first resin layer is 0.001 GPa to 0.5 GPa, and the second Young's modulus of the second resin layer is 1.0 GPa to 30 GPa.

3. The electronic component according to claim 1, wherein the first resin layer contains at least one selected from the group consisting of a silicone resin, a polyurethane resin, a low density polyethylene resin, a fluororesin, and a rubber-based resin, and
the second resin layer contains at least one selected from the group consisting of an epoxy resin, an acrylic resin, a high density polyethylene resin, a nylon resin, polystyrene, and a polyester resin.

4. The electronic component according to claim 1, wherein a combination of the first resin layer and the second resin layer is a combination of a silicone resin or crosslinked resin thereof and an epoxy resin or crosslinked resin thereof, a combination of a fluororesin and an epoxy resin or crosslinked resin thereof, a combination of a low density polyethylene resin and an epoxy resin or crosslinked resin thereof, or a combination of a fluororesin and a nylon resin.

5. The electronic component according to claim 1, wherein the first resin layer and the second resin layer are formed of a resin composition which is cured by LTV rays.

6. The electronic component according to claim 5, wherein the resin composition which is cured by UV rays contains at least one selected from the group consisting of a UV curable epoxy resin, a UV curable acrylic resin, a LTV curable polyester resin, a LTV curable polyurethane resin, and a UV curable silicone resin.

7. The electronic component according to claim 1, wherein the solder contains Sn together with Bi, or Ag, or Bi and Ag.

8. The electronic component according to claim 1, wherein the solder contains Cu powder.

9. Electronic equipment, comprising:
an electronic component, which contains:
a wiring board containing electrode pads;
a component including a plurality of electrodes, the component being mounted on the wiring board;
a sealing resin covering the component; and
a plurality of terminals configured to connect a wiring provided within the wiring board to an external substrate,
wherein the plurality of electrodes and the electrode pads are connected with solder, and
wherein a first resin layer and a second resin layer are provided between the solder and the sealing resin in this order from the side of the solder, where the first resin layer has a first Young's modulus and the second resin layer has a second Young's modulus larger than the first Young's modulus.

10. The electronic equipment according to claim 9, wherein the electronic equipment is an arithmetic processing unit, a communication equipment, an office appliance, an AV equipment, or a domestic appliance.

11. A soldering paste, comprising:
solder; and
a resin composition containing a material for forming a first resin layer having a first Young's modulus, and a material for forming a second resin layer having a second Young's modulus larger than the first Young's modulus.

12. The soldering paste according to claim 11, wherein the first Young's modulus of the first resin layer is 0.001 GPa to 0.5 GPa, and the second Young's modulus of the second resin layer is 1.0 GPa to 30 GPa.

13. The soldering paste according to claim 11, wherein the material for forming the first resin layer is at least one selected from the group consisting of a silicone resin, a polyurethane resin, a low density polyethylene resin, a fluororesin, and a rubber-based resin, and the material for forming the second resin layer is at least one selected from the group consisting of an epoxy resin, an acrylic resin, a high density polyethylene resin, a nylon resin, polystyrene, and a polyester resin.

14. The soldering paste according to claim 11, wherein a combination of the material for forming the first resin layer and the material for forming the second resin layer is a combination of a silicone resin and an epoxy resin, a combination of a fluororesin and an epoxy resin, a combination of a low density polyethylene resin and an epoxy resin, or a combination of a fluororesin and a nylon resin.

15. The soldering paste according to claim 11, wherein the resin composition is cured by UV rays.

16. The soldering paste according to claim 15, wherein the resin composition which is cured by UV rays is at least one selected from the group consisting of a UV curable epoxy resin, a UV curable acrylic resin, a UV curable polyester resin, a UV curable polyurethane resin, and a UV curable silicone resin.

17. The soldering paste according to claim 11, wherein the solder contains Sn together with Bi, or Ag, or Bi and Ag.

18. The soldering paste according to claim 11, wherein the solder contains Cu powder.

19. The soldering paste according to claim 11, wherein an amount of the solder is 80 parts by mass to 95 parts by mass relative to 100 parts by mass of the soldering paste.

20. The soldering paste according to claim 11, wherein an amount of the material for forming the first resin layer is 1 part by mass to 19 parts by mass relative to 100 parts by mass of the soldering paste, and an amount of the material for forming the second resin layer is 1 part by mass to 19 parts by mass relative to 100 parts by mass of the soldering paste.
